(19) United States
(12) Patent Application Publication
(10) Pub. No.: US 2026/0190907 A1
(43) Pub. Date: Jul. 2, 2026

(54) SEMICONDUCTOR MANUFACTURING EQUIPMENT AND SEMICONDUCTOR MANUFACTURING METHOD

(71) Applicant: SEMES CO., LTD., Cheonan-si (KR)

(72) Inventors: Jang Jin LEE, Cheonan-si (KR); Hyun YOON, Cheonan-si (KR); Yong Jun KIM, Cheonan-si (KR); Kang Sul KIM, Cheonan-si (KR); SERYEYOHAN CHO, Cheonan-si (KR); Ki Hoon CHOI, Cheonan-si (KR)

(73) Assignee: SEMES CO., LTD., Cheonan-si (KR)

(21) Appl. No.: 19/428,123

(22) Filed: Dec. 20, 2025

(30) Foreign Application Priority Data
Dec. 30, 2024 (KR) 10-2024-0200025

(51) Int. Cl. H10P 72/00; H01J 37/32; H10P 50/26; H10P 50/66

(52) U.S. Cl. CPC H10P 72/0421; H01J 37/32743; H01J 37/32834; H01J 37/32899; H10P 50/267; H10P 50/667; H10P 72/0424; H01J 2237/184; H01J 2237/334

(57) ABSTRACT

Disclosed relates to semiconductor manufacturing equipment and a semiconductor manufacturing method and, more particularly to semiconductor manufacturing equipment and a semiconductor manufacturing method, the semiconductor manufacturing equipment including a process station in which a plurality of dry processing units is provided on an upper level and a plurality of wet processing units is provided on a lower level, and a cover surrounds each dry processing unit and each wet processing unit to shield electromagnetic waves of the dry processing unit.

### CROSS REFERENCE TO RELATED APPLICATION

The present application claims priority to Korean Patent Application No. 10-2024-0200025, filed Dec. 30, 2024, the entire contents of which are incorporated herein for all purposes by this reference.

### BACKGROUND OF THE INVENTION

### Field of the Invention

The present disclosure relates to semiconductor manufacturing equipment and a semiconductor manufacturing method. More particularly, the present disclosure relates to a technology capable of achieving a multi-cycle process with a dry processing unit on an upper level of manufacturing equipment and a wet processing unit on a lower level, and of reducing noise with an electromagnetic waves shielding cover.

### Description of the Related Art

Semiconductor devices are manufactured with processes such as depositing, etching, photolithography, ashing, packaging, etc. At this point, the etching process is a process of removing a selected region of a film formed on a substrate and utilizes wet etching and dry etching. Meanwhile, a method in which dry etching and wet etching may be repeatedly performed to remove the film may be utilized.

Conventionally, for the process of alternately repeating dry etching and wet etching, the etching process is performed with dry processing equipment and wet processing equipment that are separately provided, as semiconductor processing equipment. In other words, the substrate is dry-etched in the dry processing equipment, transferred to the wet processing equipment using an overhead transport (OHT), and then processed in the wet processing process. Otherwise, the substrate is wet-etched in the wet processing equipment, transferred to the dry processing equipment using the OHT, and then processed in the dry processing process. However, when the process of transporting the substrate using the OHT is delayed, the relative humidity in a front opening unified pod (FOUP) of the OHT transferring the substrate is increased, thereby generating time-elapsed particles on the substrate.

Meanwhile, a proposal was also made to configure the dry etching equipment and the wet etching equipment together in a single piece of semiconductor manufacturing equipment, but due to electromagnetic waves generated during the plasma processing of the dry etching, noise is generated in the wet etching equipment and the transfer module, thereby deteriorating the accuracy in the substrate treatment process.

Therefore, semiconductor manufacturing equipment techniques capable of preventing noise generated from the plasma processing and performing both the dry processing process and the wet processing process are required.

### SUMMARY OF THE INVENTION

Accordingly, the present disclosure has been made keeping in mind the above problems occurring in the related art, and the present disclosure is intended to propose a single piece of semiconductor manufacturing equipment, which is capable of performing both a dry processing process and a wet processing process.

Another objective of the present disclosure is to provide semiconductor manufacturing equipment, which is capable of reducing a transfer distance or a footprint of a substrate during a substrate treatment process in which a dry processing process and a wet processing process are alternately repeated.

Yet another objective of the present disclosure is to provide semiconductor manufacturing equipment, which is capable of preventing noise from being generated during a dry processing process, thereby preventing the accuracy of a wet processing device and a transfer module from being deteriorated due to electromagnetic waves generated from plasma.

The objective of the present disclosure is not limited to the above description, and other objectives and advantages not mentioned will be clearly understood by those skilled in the art from the subsequent description.

According to the present disclosure, there is provided semiconductor manufacturing equipment that processes a substrate, and the semiconductor manufacturing equipment includes a load port configured to load the substrate at first side of the semiconductor manufacturing equipment, an index module extending in a first direction from the load port and configured to transfer the substrate, and a process station connected to the index module and extending in a second direction, and including a plurality of levels, and the process station includes a plurality of dry processing units on an upper level and a plurality of wet processing units on a lower level.

The semiconductor manufacturing equipment and the semiconductor manufacturing method according to the present disclosure can reduce a footprint in the semiconductor treatment process in which dry etching and wet etching are alternately performed, by providing a single piece of semiconductor manufacturing equipment having the dry processing unit on the upper level and the wet processing unit on the lower level.

In other words, as transfer distances and time of the substrate are reduced, a problem of damage to the substrate can be eliminated, and the required time of the substrate treatment process can be reduced.

Furthermore, the semiconductor manufacturing equipment is equipped with a shielding cover that blocks electromagnetic waves at each processing unit, thereby preventing electromagnetic waves generated in the dry processing unit and reducing and blocking noise generated from each device.

The effect of the present disclosure is not limited to the above description, and other effects not mentioned will be clearly understood by those skilled in the art from the subsequent description.

### BRIEF DESCRIPTION OF THE DRAWINGS

FIG. 1 is a side view showing a side surface of semiconductor manufacturing equipment according to an embodiment of the present disclosure.

FIG. 2 is a top view showing an upper level of the semiconductor manufacturing equipment according to the embodiment of the present disclosure.

FIG. 3 is a top view showing a lower level of the semiconductor manufacturing equipment according to the embodiment of the present disclosure.

FIG. 4 is a view showing a configuration of a dry processing unit according to the embodiment of the present disclosure.

FIG. 5 is a door portion of the dry processing unit according to the embodiment of the present disclosure.

FIG. 6 is a view showing a configuration of a wet processing unit according to the embodiment of the present disclosure.

FIG. 7 is a flow chart showing a substrate manufacturing process of the semiconductor manufacturing equipment according to the embodiment of the present disclosure.

FIG. 8 is a flow chart showing a substrate manufacturing process of the semiconductor manufacturing equipment according to another embodiment of the present disclosure.

### DETAILED DESCRIPTION OF THE DISCLOSURE

Hereinbelow, exemplary embodiments of the present disclosure will be described in detail with reference to the accompanying drawings such that the present disclosure can be easily embodied by one of ordinary skill in the art to which the present disclosure belongs. The present disclosure may be changed to various embodiments and the scope and spirit of the present disclosure are not limited to the embodiments described hereinbelow.

In the following description, if it is decided that the detailed description of known function or configuration related to the present disclosure makes the subject matter of the present disclosure unclear, the detailed description is omitted, and the same reference numerals will be used throughout the drawings to refer to the elements or parts with same or similar function or operation.

Furthermore, in various embodiments, an element with same configuration will be described in a representative embodiment by using the same reference numeral, and different configuration from the representative embodiment will be described in other embodiment.

Other words used to describe the relationship between elements should be interpreted in a like fashion such as “between” versus “directly between”, “adjacent” versus “directly adjacent”, etc. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this invention belongs.

It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinbelow, semiconductor manufacturing equipment and a semiconductor manufacturing method according to the present disclosure will be described, the semiconductor manufacturing equipment including a dry processing unit on an upper level and a wet processing unit on a lower level, thereby performing a dry processing and a wet processing alternately and repeatedly.

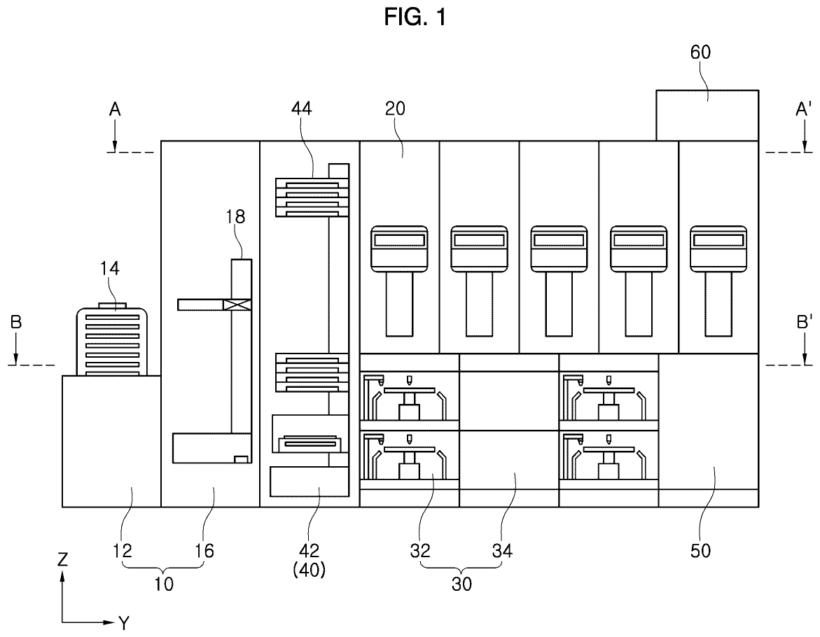

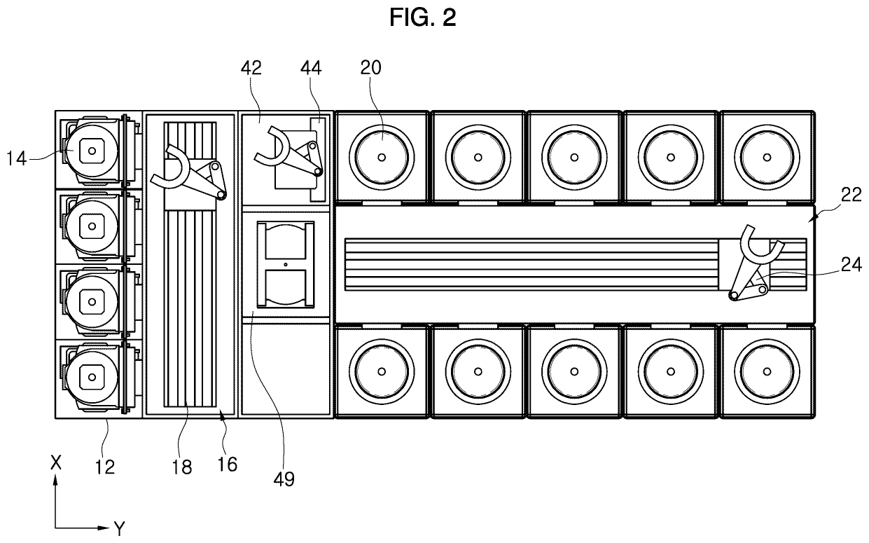

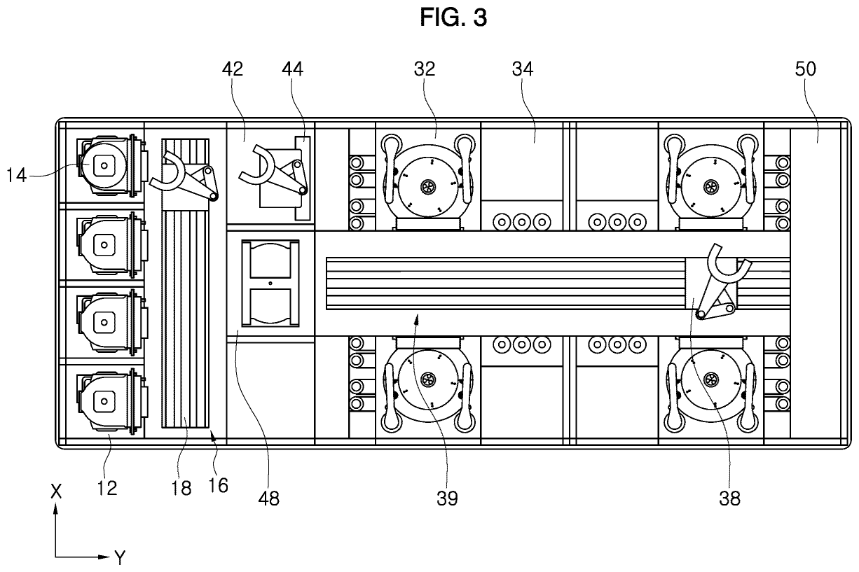

FIG. 1 is a view showing a side surface of semiconductor manufacturing equipment 1 according to the embodiment of the present disclosure. FIG. 2 is a top view showing an upper level of the semiconductor manufacturing equipment 1, the view being taken along line A-A′ of FIG. 1. FIG. 3 is a top view showing a lower level of the semiconductor manufacturing equipment 1, the view being taken along line B-B′ of FIG. 1.

A configuration of the semiconductor manufacturing equipment 1 will be described based on FIG. 1, with reference to FIGS. 2 and 3.

For example, the semiconductor manufacturing equipment 1 includes: a loading unit 10 accommodating a cassette (front opening unified pod; FOUP, 14) in which a substrate is stored, and configured to remove a substrate from the cassette 14 or insert the substrate in the cassette 14, a dry processing unit 20 performing dry processing with respect to the substrate, a wet processing unit 30 performing wet processing, a substrate transfer unit 40 transferring the substrate, a control box 50 controlling the processing, and an exhaust box 60 exhausting fume and gas generated during the processing to the outside space. Meanwhile, the semiconductor manufacturing equipment 1 includes a process station, in which a substrate is processed, composed of multiple levels, and the dry processing unit 20 is provided on an upper level of the process station, and the wet processing unit 30 is provided on a lower level thereof. Moreover, the semiconductor manufacturing equipment 1 may include one or more dry processing units 20 on the upper level. Furthermore, the semiconductor manufacturing equipment 1 may include one or more wet processing units 30 on the lower level.

The loading unit 10 includes a load port 12 on which the cassette 14 storing a substrate is seated, and an index module 16 removing a substrate from the cassette 14 seated on the load port 12 or inserting a substrate completed in the processing, into the cassette 14. The load port 12 may include a plurality of load ports 12 arranged on a first side of the semiconductor manufacturing equipment 1 in a first direction (e.g., X-axial direction), and after the cassette F that has been transferred by the overhead hoist transport (OHT) is seated, a door of the cassette 14 may be opened. The index module 16 may be arranged adjacent to the load port 12. The index module 16 may include an index robot 18 that delivers a substrate while moving in the first direction (X-axial direction), which is the arrangement direction of the load port 12. The index robot 18 may receive a substrate from the cassette 14 and deliver the substrate to the substrate transfer unit 40.

For example, the process station may be connected to the index module 16 and formed by extending in a second direction (Y-axial direction), and include the substrate transfer unit 40, the dry processing unit 20, and the wet processing unit 30. Moreover, the substrate transfer unit 40 may include a vertical transfer module 44, a first horizontal transfer module 22, a second horizontal transfer module 39, a buffer 42, and a load lock chamber 49. For example, the vertical transfer module 44 may transfer a substrate delivered from the index robot 18 to the upper level or the lower level of the process station. Furthermore, the vertical transfer module 44 may deliver the substrate from the upper level or the lower level to the index robot 18. For example, the vertical transfer module 44 may transfer the substrate from the upper level to the lower level or from the lower level to the upper level.

Referring to FIG. 2, a structure of the upper level of the semiconductor manufacturing equipment 1 will be described in detail. The upper level of the process station may include the first horizontal transfer module 22 and one or more dry processing units 20. Moreover, the pressure on the upper level of the process station may be formed to be maintained at a vacuum.

The substrate transferred to the upper level may be delivered from the vertical transfer module 44 to the dry processing unit 20 through the load lock chamber 49 and the first horizontal transfer module 22. Furthermore, the substrate may be transferred outward while being delivered from the dry processing unit 20 to the vertical transfer module 44 through the first horizontal transfer module 22 and the load lock chamber 49.

For example, the first horizontal transfer module 22 and the dry processing unit 20 may be operated under a vacuum. In other words, in order to provide a pressure equal to or similar to the process pressure of the dry processing unit 20, the pressure of the modules located on the upper level may be operated under a vacuum.

For example, the load lock chamber 49 may deliver the substrate from the vertical transfer module 44 operated under atmospheric pressure to the first horizontal transfer module 22 operated under a vacuum. Otherwise, the load lock chamber 49 may deliver the substrate from the first horizontal transfer module 22 operated under a vacuum to the vertical transfer module 44 operated under atmospheric pressure. In other words, the load lock chamber 49 may be a space that receives the substrate, adjusts pressure, and deliver the substrate, in order to transfer the substrate between two spaces having different pressures.

The first horizontal transfer module 22 may be connected to the load lock chamber 49 and extend in the second direction (Y-axial direction). A plurality of dry processing units 20 may be installed at each side portion of the first horizontal transfer module 22. In other words, a plurality of dry processing units 20 may be arranged at each side portion of the first horizontal transfer module 22 in the second direction (Y-axial direction). For example, the first horizontal transfer module 22 may deliver the substrate that is delivered from the load lock chamber 49 to each dry processing unit 20, or deliver the substrate from each dry processing unit 20 to the load lock chamber 49.

For example, the dry processing unit 20 may include the dry processing chamber to plasma-process a substrate. More specifically, the dry processing unit 20 may supply processing gas into the dry processing chamber and generate plasma, thereby etching the substrate. For example, the dry processing unit 20 may utilize various methods of plasma process devices, such as capacitively coupled plasma (CCP), inductively coupled plasma (ICP), microwave-type plasma, or the like.

Meanwhile, the semiconductor manufacturing equipment 1 may include the exhaust box 60 to discharge gas and plasma generated from the dry processing unit 20 outward. Specifically, the exhaust box 60 may include an inlet provided inside a housing to communicate with the dry processing unit 20, and an outlet communicating with the outside. Particularly, the exhaust box 60 and the dry processing unit 20 may be installed on the upper level and on the upper portion of the semiconductor manufacturing equipment 1, thereby allowing efficient thermal management. More specifically, since waste heat generated from the dry processing process has the upward-moving characteristic, the waste heat generated from the dry processing unit 20 may be discharged outward without coming into contact with the wet processing unit 30 located on the lower level. Therefore, the exhaust box 60 may discharge the heat generated on the upper level to the upper space, so that heat is not delivered to the wet processing unit 30 located on the lower level. Moreover, when gas and plasma leakage accidents occur from the dry processing unit 20, gas can be discharged from the upper level outward without passing through the wet processing unit 30, thereby reducing damage and risks caused by gas leakage.

Referring to FIG. 3, a structure of the lower level of the semiconductor manufacturing equipment 1 will be described in detail. The substrate delivered to the lower level through the vertical transfer module 44 may be delivered to the wet processing unit 30 via a buffer 48 and the second horizontal transfer module 39. Furthermore, the substrate may be transferred outward by being delivered from the wet processing unit 30 to the vertical transfer module 44 via the second horizontal transfer module 39 and the buffer 48.

For example, the buffer 48 may be a space where the substrate dry-processed on the upper level is temporarily stored. Otherwise, the buffer 48 may be a space where the substrate wet-processed on the lower level is temporarily stored.

The second horizontal transfer module 39 may be connected to the buffer 48 and extend in the second direction (Y-axial direction). A plurality of wet processing units 30 may be installed at each side portion of the second horizontal transfer module 39. In other words, a plurality of wet processing units 30 may be disposed at each side portion of the second horizontal transfer module 39 in the second direction (Y-axial direction). For example, the second horizontal transfer module 39 may deliver the substrate, which is delivered from the buffer 48, to each wet processing unit 30, or the substrate from each wet processing unit 30 to the buffer 48.

For example, on the lower level, the buffer 48, the second horizontal transfer module 39, and the wet processing unit 30 may be operated under atmospheric pressure. In other words, in order to provide a pressure equal to or similar to the process pressure of the wet processing unit 30, the pressure of the lower level may be operated under atmospheric pressure.

For example, the wet processing unit 30 may include a wet processing chamber 32, which sprays a processing liquid on a surface of the substrate to etch the surface of the substrate, and the valve box 34. More specifically, the wet processing unit 30 may spray the processing liquid on an upper end of the substrate to etch the substrate.

For example, the wet processing chamber 32 may include a nozzle supplying the processing liquid to the upper end of the substrate, which will be described below. The position of the nozzle of the wet processing chamber 32 may be adjusted above the substrate, such as a central portion, an edge portion, etc., of the substrate, thereby suppling the processing liquid. Otherwise, the nozzle of the wet processing chamber 32 may supply the processing liquid to the substrate while adjusting the vertical distance from the substrate.

For example, the valve box 34 may be connected to the wet processing chamber 32 and supply the processing liquid used in the wet processing process to the wet processing chamber 32. Otherwise, the valve box 34 may include devices that recover or discharge chemical liquid used in the wet processing chamber 32 and the wet processing process. Specifically, the valve box 34 is located on the lower level together with the wet processing chamber 32, so that the used processing liquid may be easily discharged to the outside space. Otherwise, the valve box 34 may easily supply the processing liquid, which will be supplied, to the wet processing chamber 32.

Meanwhile, the wet processing unit 30 may be installed on the lower level, thereby reducing the risks of accidents during leakage of the processing liquid. In other words, since the wet processing unit 30 is located on the lower level, the leaking processing liquid flows through a lower end without passing through the dry processing unit 20 located on the upper level. Therefore, the processing liquid may be discharged outward or eliminated without damaging the upper level where the dry processing unit 20 is located. In other words, as the wet processing unit 30 is located on the lower level, it is possible to reduce the damage and risk of a leakage accident of the processing liquid.

Referring to FIG. 1 again, the semiconductor manufacturing equipment 1 will be described. In the plasma treatment process, the dry processing unit 20 may have electromagnetic waves generated from plasma. Specifically, electromagnetic waves generated from plasma may generate noise in the semiconductor manufacturing equipment to interfere with precise processing. More specifically, electromagnetic waves generated from the dry processing unit 20 may generate noise in a transfer robot of the substrate transfer unit 40 or a nozzle control device of the wet processing unit 30 to be described below. Therefore, electromagnetic waves may interfere with the transfer robot when transferring the substrate to a precise position. Otherwise, noise may interfere with rotational speed control in the wet processing unit 30 when the support unit is rotated, and with supply position control when the nozzle supplies the processing liquid onto the substrate. Therefore, a method that can shield electromagnetic waves generated from plasma of the dry processing process is required.

The semiconductor manufacturing equipment 1 may include a cover to prevent deterioration in processing efficiency due to noise. For example, the dry processing unit 20 on the upper level may be covered with a cover to shield electromagnetic waves. Specifically, the dry processing unit 20 may include a door made of materials and patterns that can shield electromagnetic waves. For example, the wet processing unit 30 on the lower level may be covered with the cover to shield electromagnetic waves. Description of the cover and the door for shielding electromagnetic waves will be provided with configurations of the dry processing unit 20 and the wet processing unit 30 to be described below.

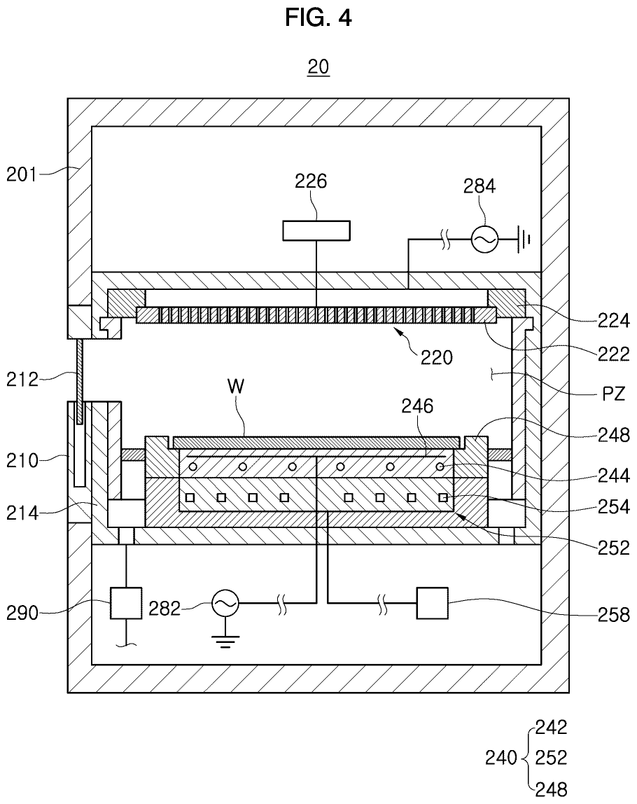

FIG. 4 is a view showing a configuration of the dry processing unit for the plasma treatment. The dry processing unit 20 includes a dry chamber cover 201 covering the inner devices for dry processing, a dry processing chamber 214 forming a plasma processing space PZ to process the substrate W, and a substrate support assembly 240 on which the substrate W is seated and supported. Furthermore, the dry processing unit 20 may include a lower power source 282 that supplies power used for generating plasma in the plasma processing space PZ to the substrate support assembly 240. Moreover, the dry processing unit 20 may include a heating gas supply means 258 that supplies heating gas to adjust the temperature of the substrate W. Moreover, the dry processing unit 20 may include a door 210 separating and shielding the inside space of the dry processing chamber 214 and the outside space of the dry processing unit 20, and an exhaust device 290 discharging byproducts and gas that are generated from the plasma treatment process, outwards.

The dry processing chamber 214 provides the plasma processing space PZ, which is used to process the substrate W. Members for plasma-processing the substrate W may be installed in the inside space of the dry processing chamber 214. An upper electrode 220 and a gas supply member may be located at an upper portion of the dry processing chamber 214. The upper electrode 220 may be grounded. Furthermore, the upper electrode 220 may be a shower head that distributes processing gas and supplies it to the plasma processing space PZ. A gas source 226 may supply processing gas to the upper electrode 220, and the processing gas may be supplied into the plasma processing space PZ via the upper electrode 220.

The substrate support assembly 240 is provided at a lower portion of the dry processing chamber 214. An electrode 246 is provided in the substrate support assembly 240, and the substrate support assembly 240 may generate an electrostatic field. In other words, the substrate support assembly 240 may support and hold the substrate W by exerting an electrostatic force on the substrate W. Furthermore, the substrate support assembly 240 may be utilized as a lower electrode that is used to generate plasma.

The substrate support assembly 240 may include an upper plate 242 that supports the substrate W with an electrostatic force, and an edge ring 248 that surrounded a base plate 252 and the substrate W.

The substrate W to be plasma-processed is seated on the upper plate 242, and the upper plate 242 may include a heater (not shown) embedded therein. Although not shown in the drawings, the upper plate 242 may include a plurality of heating regions provided by the heater (not shown). The upper plate 242 is a structure that supports the substrate W at a lower portion of the substrate W, and may include the electrode 246 formed therein. The upper plate 242 may be made of ceramic materials that include quartz, etc.

The base plate 252 may include a cooling path 254 that supports a lower portion of the upper plate 242 and provides an inner space for a cooling fluid to flow therein. Moreover, the base plate 252 may be formed in a circular plate made of a metal material including aluminum (Al), etc. The base plate 252 may have a diameter greater than that of the upper plate 242. The cooling path 254 may be formed at a lower portion of the base plate 252, and cooling fluid or refrigerant may be supplied to the cooling path 254. An outer surface of the base plate 252 may include a coating layer made of alumina (Al203). The coating layer prevents the base plate 252, made of metal (e.g., Al), from being exposed to the external environment, particularly plasma. Furthermore, a bonding layer may be formed between the upper plate 242 and the base plate 252 to bond the upper plate 242 and the base plate 252 to each other.

The lower power source 282 supplies power to the lower electrode provided at the substrate support assembly 240. The lower power source 282 may be provided to control the properties of plasma. The lower power source 282 may, for example, be provided to adjust the density of plasma or ion bombardment energy.

Meanwhile, the dry processing unit 20 may include an upper power source 284 that is connected to the upper electrode 220 and supplies power. However, unlike the provision in the present disclosure, the lower power source 282 may be connected to both the upper electrode 220 and the substrate support assembly 240 to generate plasma. Furthermore, the upper power source 284 or the lower power source 282 may include one or more power sources. When a plurality of upper power sources 284 is provided, the dry processing unit 20 may include a matching network electrically connected to the plurality of upper power sources. The matching network may match frequency powers with different sizes input from the upper power source 284 and the lower power source 282, and supply it to the upper electrode 220 and the substrate support assembly 240. Meanwhile, the base plate 252 may include an impedance matching circuit (not shown) to achieve impedance matching. Furthermore, the lower power source 282 may be connected to a cluster tool controller that is a control device including one or more processors and memories.

The upper electrode 220 may generate plasma from gas remaining in the plasma processing space PZ. Herein, the plasma processing space PZ is a space located above the substrate support assembly 240, within the inner space of the dry processing chamber 214. The upper electrode 220 may generate electromagnetic field from power supplied from the upper power source 284.

The gas source 226 supplies etching gas that is used to process the substrate W, as processing gas. As a gas supplier, the upper electrode 220 may include a plurality of spraying holes to spray the gas into the dry processing chamber 214. The gas supplier may be a shower head including a plurality of gas spraying holes. Furthermore, the gas supplier may be a structure including one or more gas supply nozzles.

Meanwhile, a structure of the dry processing unit of the present disclosure is not limited to a capacitively coupled plasma (CCP) processing method, as shown in FIG. 4. If necessary, the structure of the dry processing unit of the present disclosure may utilize an inductively coupled plasma (ICP) processing method or a microwave-type plasma processing method.

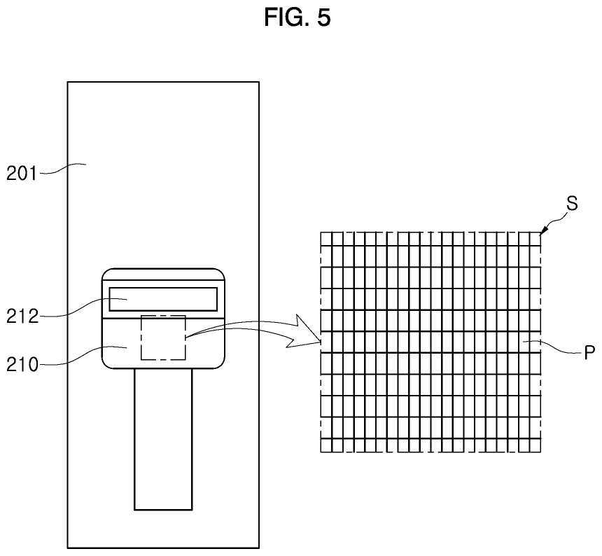

A structure of shielding electromagnetic waves generated from the dry processing unit 20 will be described with reference to FIG. 5. The dry processing unit 20 may include the dry chamber cover 201 and the door 210 that are manufactured to prevent electromagnetic waves generated during the plasma processing from leaking outward. For example, the dry chamber cover 201 may be installed to cover the outside space of a dry processing chamber 214. The dry chamber cover 201 may be installed not only at a front surface of the dry processing chamber 214, but also at a lower end, an upper end, or a rear end. The door 210 may include a shutter 212 capable of opening and closing a passage through which the substrate is transferred to the dry processing chamber 214.

The door of the dry processing unit 20 of the related art is a passage through which the substrate is transferred to or from the dry processing unit 20, and has a problem in that electromagnetic waves may easily penetrate therethrough. Therefore, in the present disclosure, the dry chamber cover 201 and the door 210 are made of a material and a structure that can shield electromagnetic waves, thereby preventing electromagnetic waves from being transmitted to the outside space of the dry processing unit 20.

For example, the dry chamber cover 201 may be made of a metal panel that can reflect and absorb electromagnetic waves. Moreover, a material of the panel of the dry chamber cover 201 to reflect and absorb electromagnetic waves may include aluminum (Al), polyimide, etc. For example, the door 210 may be made of a metal panel S on which a pattern P is formed from a nanocomposite material to absorb electromagnetic waves, thereby shielding electromagnetic waves. Moreover, the material of nanocomposite material used in the door 210 may include carbon nanotube, graphene, or the like. Moreover, the pattern of nanocomposite material used in the dry chamber cover 201 and the door may have a grid form.

As the material and structure for shielding electromagnetic waves are used in the dry chamber cover 201 and the door 210, it is possible to prevent electromagnetic waves generated from the internal space of the dry processing chamber 214 from being transmitted outward. More specifically, it is possible to prevent the generation of noise when each transfer robot of the substrate transfer unit 40 transfers the substrate to a precise position in the semiconductor manufacturing equipment 1. In other words, the transfer robot may transfer the substrate to a precise position. Otherwise, it is possible to prevent noise from being generated in a device within the wet processing unit 30, thereby improving the accuracy of each processing.

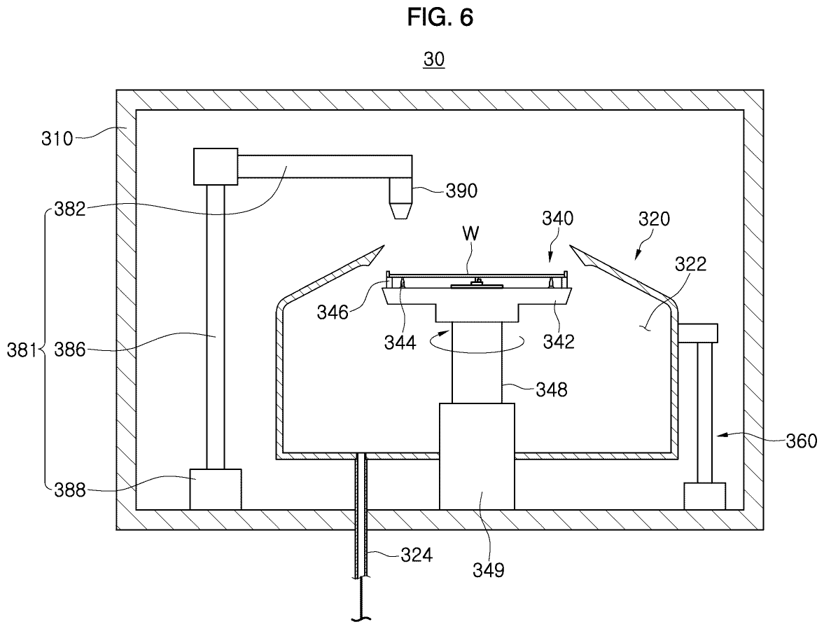

FIG. 6 is a view showing the configuration of the wet processing unit of the present disclosure.

The wet processing unit 30 includes a wet processing chamber 310 that provides a space where the substrate is wet-processed. For example, the wet processing chamber 310 includes a processing container 210, a support unit 340, a raising and lowering unit 360, and a processing liquid supply unit 380. The processing container 210 provides a processing space where the process of processing the substrate W is performed. The processing container 210 has a form of container with an open upper portion. Furthermore, the processing container 210 includes a recovery container into which a solution is recovered, and different processing liquids of processing liquids used in the processes are recovered. The recovery container has a form of ring surrounding the support unit 340. An inner space 322 of the recovery container is a space into which the processing liquid flowing into the recovery container is discharged, and may be connected to a recovery line 324 connected to a lower end of the recovery container. The recovery line 324 is connected to the lower end of the recovery container so that the processing liquid may be delivered to the valve box 34. More specifically, the processing liquid discharged outward via the recovery line 324 may be discharged to a lower end of the semiconductor manufacturing equipment 1 via the valve box 34. Otherwise, the processing liquid may be provided as an external

### Processing Liquid Regenerative System (not Shown) and Reused.

The support unit 340 supports the substrate W in the processing space. The support unit 340 may support and rotate the substrate W during performing the process. The support unit 340 may include a support body 342, a support pin 344, a chuck pin 346, and a rotational driving device 349. The support body 342 has an upper surface and a lower surface that are generally formed into circular shapes. The lower surface has a diameter less than that of the upper surface. The upper surface and the lower surface may be arranged with concentric central shafts.

A plurality of support pins 344 may be provided. Each support pin 344 may be formed by protruding upward from an upper surface of the support body 342. Specifically, each support pin 344 may be located at a position spaced inward from an upper edge of the support body 342 at a predetermined distance, and arranged in a circumferential direction. In other words, the plurality of support pins 344 may support a lower surface of the substrate W seated on the support unit 340 in the circumferential direction. More specifically, each support pin 344 supports an edge of the rear surface of the substrate W to allow the substrate W to maintain a certain gap from an upper surface of the support body 342.

A plurality of chuck pins 346 is provided. Each chuck pin 346 is arranged farther from a central portion of the support body 342 than the support pin 344. Each chuck pin 346 may be formed by protruding upward from the support body 342. Each chuck pin 346 supports a lateral portion of the substrate W to prevent the substrate W from being deviated from its regular position and moved sideways when the support unit 340 is rotated.

Each chuck pin 346 may be provided to be movable linearly to the central portion and an edge portion along a radial direction of the support body 342. For example, when the substrate W is loaded on or unloaded from the support unit 340, each chuck pin 346 may be located at an edge portion of the support body 342. In other words, an inner surface of each chuck pin 346 is spaced apart from an outer surface of the substrate W, so that the substrate W may be freely moved from the inner space of each chuck pin 346. Moreover, each chuck pin 346 may be moved to the central portion to prevent the substrate W from being deviated during the process of processing the substrate W. In other words, the inner surface of each chuck pin 346 may come into close contact with the outer surface of the substrate W, thereby enclosing the outer surface.

The rotational driving device 349 may be connected to the rotational driving shaft 348 and rotate the support body 342. Moreover, the support body 342 may be rotated on the rotational driving shaft 348. The rotational driving shaft 348 may have the form of a cylindrical shaft.

The raising and lowering unit 360 linearly moves the processing container 210. As the processing container 210 is moved vertically, a relative height of the processing container 210 with respect to the support unit 340 may be changed.

The processing liquid supply unit 380 may supply the processing liquid onto the upper surface of the substrate W. A plurality of processing liquid supply units 380 may be provided, and different types of processing liquids may be supplied through the processing liquid supply units 380. Each processing liquid supply unit 380 may include a moving member 381 and a nozzle 390.

The moving member 381 may adjust the position of the nozzle 390. More specifically, the moving member 381 may move the nozzle 390 to a process position and a waiting position. For example, when the moving member 381 moves the nozzle 390 to a process position, the nozzle 390 may be installed above the substrate W so that a discharge port faces the upper surface of the substrate. Moreover, the nozzle 390 may supply the processing liquid at a first supply position corresponding to the central portion of the substrate W, or a second supply position corresponding to the edge portion of the substrate W, depending on the process. For example, when the moving member 381 moves the nozzle 390 to the waiting position, the nozzle 390 may be moved to a position deviated from the process position.

The moving member 381 may include a support shaft 386, an arm 382, and an actuator 388. The support shaft 386 may be positioned at one side space of the processing container 210, and be connected to the actuator 388 to be rotated and moved vertically. The arm 382 extends from an upper end of the support shaft 386 in a direction perpendicular to a longitudinal direction of the support shaft 386. The nozzle 390 may be securely coupled to an end of the arm 382. The nozzle 390 may be connected to the arm 382 to be moved to the process position and the waiting position by the actuator 388.

For example, the processing liquid may be a chemical, a rinse liquid, or an organic solvent. The processing liquid may be an etching liquid having acid or base properties. A rinse liquid may be pure water (H2O), and an organic solvent may be isopropyl alcohol (IPA).

Meanwhile, the wet processing unit 30 may include a wet chamber cover to cover the outside space of the wet processing chamber 310. For example, the wet chamber cover may be made of a metal panel that can reflect and absorb electromagnetic waves. Moreover, a material of the metal panel of the wet chamber cover to reflect and absorb electromagnetic waves may include aluminum (Al), polyimide, etc.

The wet chamber cover may prevent electromagnetic waves generated in the dry processing unit 20 from being transmitted to the inner space of the wet processing chamber 310. Specifically, the wet chamber cover may prevent noise from being generated in the inner components of the wet processing chamber 310. More specifically, the wet chamber cover prevents noise from being generated during the wet processing process, thereby precisely controlling rotational speed of the support unit 340 and position adjustment of the nozzle 390.

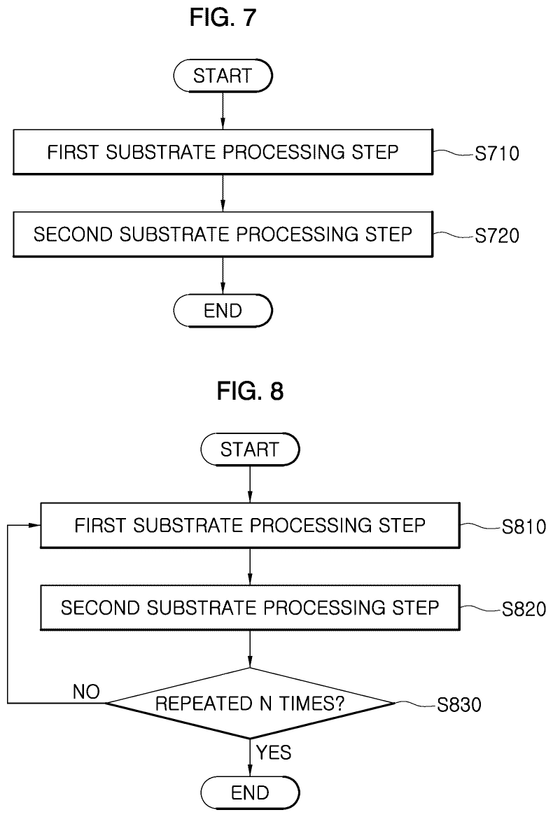

FIG. 7 is a flow chart showing a substrate manufacturing process of the semiconductor manufacturing equipment according to the embodiment of the present disclosure.

The semiconductor manufacturing method of the present disclosure may include a first substrate processing step S710 and a second substrate processing step S720. For example, the first substrate processing step S710 may be a dry substrate processing step. Moreover, the second substrate processing step S720 may be a wet substrate processing step. Otherwise, the first substrate processing step S710 may be the wet substrate processing step, and the second substrate processing step S720 may be the dry processing step. In other words, the semiconductor manufacturing equipment 1 may perform both dry processing and wet processing for the same substrate inside the same equipment. Meanwhile, the first substrate processing step S710 and the second substrate processing step S720 may be the etching process or the cleaning process. For example, the substrate treatment process may include the first substrate processing step S710 to dry-etch a substrate so that the substrate is good for being wet-etched, and the second substrate processing step S720 to wet-etch the substrate.

After the first substrate processing step S710 is finished, the semiconductor manufacturing equipment 1 performs the second substrate processing step S720 inside the semiconductor manufacturing equipment 1, thereby reducing the footprint of the substrate. Moreover, the semiconductor manufacturing equipment 1 may hold the substrate at the buffer 48 even when delays in the process occur in the first substrate processing step S710 or the second substrate processing step S720. In other words, when the process delays, the substrate completed in the process is held at the buffer 48 to prevent time-elapsed particles from being generated on the substrate.

For example, the first substrate processing step S710 may be a plasma etching process in which molybdenum on the substrate is oxidized to form a molybdenum oxide thin film. Furthermore, the second substrate processing step S720 may be a wet etching process in which the molybdenum oxide thin film is evenly removed. Moreover, after the first substrate processing step S710 is finished, the semiconductor manufacturing equipment 1 performs the second substrate processing step S720 without removing the substrate, thereby preventing time-elapsed particles from being generated on the substrate. Specifically, the semiconductor manufacturing equipment 1 can prevent native oxide from being generated on the upper surface of the molybdenum substrate during the first substrate processing step S710 and the second substrate processing step S720.

FIG. 8 is a flow chart showing a substrate manufacturing process of the semiconductor manufacturing equipment according to another embodiment of the present disclosure.

In FIG. 8, a first substrate processing step S810 and a second substrate processing step S820 may be the same as the first substrate processing step S710 and the second substrate processing step S720 in FIG. 7. Meanwhile, the first substrate processing step S810 and the second substrate processing step S820 in FIG. 8 may be repeatedly performed.

For example, the semiconductor manufacturing equipment 1 may perform the first substrate processing step S810 and the second substrate processing step S820 successively with respect to the same substrate, and then perform again the first substrate processing step S810 and the second substrate processing step S820. Otherwise, the semiconductor manufacturing equipment 1 may alternately repeat the first substrate processing step S810 and the second substrate processing step S820 by N times, which is a natural number greater than or equal to 2.

For example, the semiconductor manufacturing equipment 1 may discharge heat generated during the first substrate processing step S810, i.e., the dry processing step, via the exhaust box 60 outward. In other words, heat generated during the first substrate processing step S810 may be discharged outward without being delivered to the second substrate processing step S820, in which the wet processing step is performed. Therefore, the semiconductor manufacturing equipment 1 may control temperature adjustment of the dry processing unit 20 and the wet processing unit 30.

Meanwhile, the semiconductor manufacturing method of the semiconductor manufacturing equipment 1 of the present disclosure is not limited to the above description, and may include at least one first substrate processing step S810 and at least one second substrate processing step S820. Moreover, the first substrate processing step S810 and the second substrate processing step S820 do not necessarily have to be performed alternately, and the semiconductor manufacturing method of the present disclosure may include a semiconductor manufacturing method that can perform both the wet processing process and the dry processing process in a single piece of equipment.

The embodiments of the present disclosure and the accompanying drawings have been provided for illustrative purposes, and it is clear that all variations and specific embodiments that those skilled in the art can easily infer within the scope of the technical concept disclosure contained in the specification and the drawings of the present disclosure are included within the scope of the present disclosure.

Therefore, the spirit of the present disclosure is not limited to the embodiments described above, and the accompanying claims and various modifications, additions, and substitutions derived from the meaning and scope of the present disclosure and the equivalent concept thereof are included in the scope of the present disclosure.

What is claimed is:

1. Semiconductor manufacturing equipment for processing a substrate, the semiconductor manufacturing equipment comprising:
a load port configured to load the substrate into a first side of the semiconductor manufacturing equipment;
an index module extending in a first direction from the load port and configured to transfer the substrate; and
a process station connected to the index module and extending in a second direction, and comprising a plurality of levels,
wherein the process station comprises a plurality of dry processing units on an upper level and a plurality of wet processing units on a lower level.

2. The semiconductor manufacturing equipment of claim 1, wherein the upper level of the process station is operated under vacuum.

3. The semiconductor manufacturing equipment of claim 2, wherein the process station further comprises a load lock chamber on the upper level that adjusts pressure between the index module and the plurality of dry processing units to transfer the substrate.

4. The semiconductor manufacturing equipment of claim 3, further comprising:
an exhaust box provided on an upper portion of the semiconductor manufacturing equipment and connected to the plurality of dry processing units.

5. The semiconductor manufacturing equipment of claim 1, wherein the lower level of the process station is operated under atmospheric pressure, and
the process station comprises a buffer located on the lower level for temporarily storing the substrate.

6. The semiconductor manufacturing equipment of claim 1, wherein the lower level of the process station comprises a valve box, which is connected to the plurality of wet processing units to supply a processing liquid to the plurality of wet processing units or discharge the processing liquid to a lower portion of the semiconductor manufacturing equipment.

7. Semiconductor manufacturing equipment for processing a substrate, the semiconductor manufacturing equipment comprising:
a load port configured to load the substrate into a first side of the semiconductor manufacturing equipment;
an index module extending in a first direction from the load port and configured to transfer the substrate; and
a process station connected to the index module, extending in a second direction, and comprising a plurality of dry processing units and a plurality of wet processing units; and
a plurality of covers configured to shield electromagnetic waves, wherein the plurality of covers surrounds the plurality of dry processing units and the plurality of wet processing units.

8. The semiconductor manufacturing equipment of claim 7, wherein a material of the plurality of covers is aluminum or polyimide.

9. The semiconductor manufacturing equipment of claim 7, wherein each of the plurality of dry processing units comprises:
a dry processing chamber that is a space in which a dry processing process is performed; and
a door comprising a shutter configured to open and close a side of the dry processing chamber through which the substrate is transferred,
wherein the door comprises a metal panel shielding electromagnetic waves.

10. The semiconductor manufacturing equipment of claim 9, wherein the metal panel of the door has a pattern formed from a nanocomposite material that shields electromagnetic waves.

11. The semiconductor manufacturing equipment of claim 10, wherein a material of the nanocomposite material is carbon nanotubes or graphene.

12. The semiconductor manufacturing equipment of claim 10, wherein the pattern of the nanocomposite material is a form of grid.

13. A semiconductor manufacturing method performed by the semiconductor manufacturing equipment of claim 1, the method comprising:
first processing a substrate, the first processing of the substrate including a dry etching process of a corresponding dry processing unit of the plurality of dry processing units; and
second processing the substrate, the second processing of the substrate including a wet etching process of a corresponding wet processing unit of the plurality of wet processing units.

14. The method of claim 13, wherein the semiconductor manufacturing equipment further comprises a plurality of covers shielding electromagnetic waves generated during the first processing of the substrate, and covering the corresponding dry processing unit and the corresponding wet processing unit.

15. The method of claim 13, wherein the semiconductor manufacturing equipment performs the second processing of the substrate after the first processing of the substrate.

16. The method of claim 15, wherein the semiconductor manufacturing equipment is configured to alternately repeat the first processing and the second processing.

17. The method of claim 13,
wherein the semiconductor manufacturing equipment further comprises an exhaust box disposed on an upper portion of the semiconductor manufacturing equipment and connected to the corresponding dry processing unit, and heat generated during the first processing is discharged through the exhaust box.

18. The method of claim 13, wherein the substrate to be inserted in the semiconductor manufacturing equipment comprises a molybdenum layer,
the dry etching process of the first processing oxidizes the molybdenum layer of the substrate, and
the molybdenum oxidized layer is etched by the wet etching process of the second processing of the substrate.
